(19) United States
(12) Patent Application Publication
(10) Pub. No.: US 2025/0349255 A1
(43) Pub. Date: Nov. 13, 2025

(54) DISPLAY APPARATUS AND ELECTRONIC APPARATUS INCLUDING THE SAME

(71) Applicant: Samsung Display Co., Ltd., Yongin-Si (KR)

(72) Inventors: Jaekeun Lim, Yongin-si (KR); Bonseog Gu, Yongin-si (KR); Jinyoung Roh, Yongin-si (KR); Haekwan Seo, Yongin-si (KR)

(21) Appl. No.: 19/206,372

(22) Filed: May 13, 2025

(30) Foreign Application Priority Data
May 13, 2024 (KR) 10-2024-0062766

(51) Int. Cl. G09G 3/3233

(52) U.S. Cl. CPC G09G 3/3233; G09G 2300/043; G09G 2300/0819; G09G 2310/08; G09G 2330/021

(57) ABSTRACT

A display apparatus is disclosed that includes a first pixel arranged in a row and an odd column, and a second pixel arranged in the row and an even column. Each of the first pixel and the second pixel includes a light-emitting diode, a first transistor configured to output a current corresponding to a data signal, a second transistor transmitting the data signal to the first transistor, and a distribution transistor connected in series between the second transistor and a data line configured to supply the data signal. While the second transistor of the first pixel and the second transistor of the second pixel are simultaneously activated, the distribution transistor of the first pixel and the distribution transistor of the second pixel are sequentially activated.

### CROSS-REFERENCE TO RELATED APPLICATION

This application is based on and claims priority under 35 U.S.C. § 119 to Korean Patent Application No. 10-2024-0062766, filed on May 13, 2024, in the Korean Intellectual Property Office, the disclosure of which is incorporated by reference herein in its entirety.

### BACKGROUND

### 1. Field

One or more embodiments relate to a display apparatus and a pixel included in the same.

### 2. Description of the Related Art

A display apparatus includes a plurality of gate lines, a plurality of data lines, and a plurality of pixels connected thereto. In order to apply a data signal to each of the plurality of data lines, a data driving circuit has to provide a plurality of output lines, the number of which corresponds to the number of data lines and the number of integrated. As size of display devices has increased and resolution has improved, the costs of manufacturing have increased.

### SUMMARY

One or more embodiments include a display apparatus configured to reduce the number of output lines of a data driving circuit and an operating method of the display apparatus. However, this is an example and does not limit the scope of the disclosure.

Additional aspects will be set forth in part in the description which follows and, in part, will be apparent from the description, or may be learned by practice of the presented embodiments of the disclosure.

According to one or more embodiments, a display apparatus includes a first pixel arranged in a row and an odd column and a second pixel arranged in the row and an even column, wherein each of the first pixel and the second pixel includes a light-emitting diode, a first transistor configured to output a current corresponding to a data signal, a second transistor transmitting the data signal to the first transistor, and a distribution transistor connected in series between the second transistor and a data line configured to supply the data signal, wherein, while the second transistor of the first pixel and the second transistor of the second pixel are simultaneously activated, the distribution transistor of the first pixel and the distribution transistor of the second pixel are sequentially activated.

The display apparatus may further include a first data line connected to the first pixel, a second data line connected to the second pixel, an output line connected to the first data line and the second data line and a driving circuit connected to the output line and configured to supply the data signal through the output line.

Each of the first pixel and the second pixel further may include a third transistor connected to a gate of the first transistor and a first terminal of the first transistor, a fourth transistor connected to the gate of the first transistor and a first initialization voltage line, a fifth transistor connected to a driving voltage line and the first terminal of the first transistor, a sixth transistor connected to a second terminal of the first transistor and the light-emitting diode, a seventh transistor connected to the light-emitting diode and a second initialization voltage line, and a capacitor connected to the gate of the first transistor and the light-emitting diode.

The first transistor of each of the first pixel and the second pixel may be connected to the light-emitting diode, and the first transistor may further include a back gate facing the gate of the first transistor.

The display apparatus may further include a first gate line configured to supply a first gate signal to the second transistor and the third transistor of the first pixel, and to the second transistor and the third transistor of the second pixel, a second gate line configured to supply a second gate signal to the fourth transistor of the first pixel and the fourth transistor of the second pixel, a third gate line configured to supply a third gate signal to the fifth transistor and the sixth transistor of the first pixel, and to the fifth transistor and the sixth transistor of the second pixel, and a fourth gate line configured to supply a fourth gate signal to the seventh transistor of the first pixel and the seventh transistor of the second pixel.

A conductivity type of the distribution transistor of the first pixel may be same as a conductivity type of the distribution transistor of the second pixel.

The fourth gate signal supplied to the seventh transistor of the second pixel may be delayed from the fourth gate signal supplied to the seventh transistor of the first pixel, the fourth gate signal supplied to the seventh transistor of the first pixel and the fourth gate signal supplied to the distribution transistor of the first pixel may have same timings as each other, and the fourth gate signal supplied to the seventh transistor of the second pixel and the fourth gate signal supplied to the distribution transistor of the second pixel may have same timings as each other.

A period in which the first gate signal is a level voltage for activating the second transistor may include a first sub-period and a second sub-period following the first sub-period, a period in which the fourth gate signal is a level voltage for activating the distribution transistor of the first pixel may overlap the first sub-period, a period in which the fourth gate signal is a level voltage for activating the distribution transistor of the second pixel may overlap the second sub-period, and the period in which the fourth gate signal is the level voltage for activating the distribution transistor of the first pixel and the period in which the fourth gate signal is the level voltage for activating the distribution transistor of the second pixel may not overlap each other.

The second gate signal delayed from the second gate signal supplied to the fourth transistor of the first pixel may be supplied to the distribution transistor of the first pixel, the second gate signal delayed from the second gate signal supplied to the fourth transistor of the second pixel may be supplied to the distribution transistor of the second pixel, the second gate signal supplied to the fourth transistor of the first pixel and the second gate signal supplied to the fourth transistor of the second pixel may have same timings as each other, and the second gate signal supplied to the distribution transistor of the second pixel may be delayed from the second gate signal supplied to the distribution transistor of the first pixel.

A period in which the first gate signal is a level voltage for activating the second transistor may include a first sub-period and a second sub-period following the first sub-period, a period in which the second gate signal is a level voltage for activating the distribution transistor of the first pixel may overlap the first sub-period, a period in which the second gate signal is a level voltage for activating the distribution transistor of the second pixel may overlap the second sub-period, and the period in which the second gate signal is the level voltage for activating the distribution transistor of the first pixel and the period in which the second gate signal is the level voltage for activating the distribution transistor of the second pixel may not overlap each other.

A period in which the fourth gate signal is a level voltage for activating the seventh transistor may overlap the period in which the first gate signal is the level voltage for activating the second transistor.

A conductivity type of the distribution transistor of the first pixel may be different from a conductivity type of the distribution transistor of the second pixel.

The third gate signal delayed from the third gate signal supplied to the fifth transistor of the first pixel may be supplied to the distribution transistor of the first pixel and the distribution transistor of the second pixel.

In a period in which the first gate signal is a level voltage for activating the second transistor, a voltage level of the third gate signal supplied to the distribution transistor of the first pixel and the distribution transistor of the second pixel may be changed.

A period in which the fourth gate signal is a level voltage for activating the seventh transistor may overlap the period in which the first gate signal is the level voltage for activating the second transistor.

A conductivity type of the seventh transistor may be different from a conductivity type of the second transistor.

According to one or more embodiments, a display apparatus includes a pixel area including a first pixel arranged in a row and an odd column and a second pixel arranged in the row and an even column and a gate driving circuit configured to output a gate signal to the first pixel and the second pixel. Each of the first pixel and the second pixel may include a light-emitting diode, a first transistor configured to output a current corresponding to a data signal, a second transistor transmitting the data signal to the first transistor and configured to receive a first gate signal, and a distribution transistor connected in series between the second transistor and a data line configured to supply the data signal and configured to receive a second gate signal. A conductivity type of the distribution transistor of the first pixel may be same as a conductivity type of the distribution transistor of the second pixel. The second gate signal output by the gate driving circuit to the distribution transistor of the second pixel may be delayed from the second gate signal output to the distribution transistor of the first pixel. During a first sub-period of a period in which the second transistors of the first pixel and the second pixel are simultaneously activated in response to the first gate signal output by the gate driving circuit, the distribution transistor of the first pixel may be activated and the distribution transistor of the second pixel may be not activated, and during a second sub-period of the period, the distribution transistor of the first pixel may be not activated and the distribution transistor of the second pixel may be activated.

The display apparatus may further include a first data line connected to the first pixel, a second data line connected to the second pixel, an output line connected to the first data line and the second data line and a data driving circuit connected to the output line and configured to supply the data signal through the output line.

According to one or more embodiments, a display apparatus includes a pixel area including a first pixel arranged in a row and an odd column and a second pixel arranged in the row and an even column and a gate driving circuit configured to output a gate signal to the first pixel and the second pixel. Each of the first pixel and the second pixel may include a light-emitting diode, a first transistor configured to output a current corresponding to a data signal, a second transistor transmitting the data signal to the first transistor and configured to receive a first gate signal, and a distribution transistor connected in series between the second transistor and a data line configured to supply the data signal and to receive a second gate signal. A conductivity type of the distribution transistor of the first pixel may be different from a conductivity type of the distribution transistor of the second pixel. In a period in which the second transistors of the first pixel and the second pixel are simultaneously activated in response to the first gate signal output by the gate driving circuit, a voltage level of the second gate signal output by the gate driving circuit may be changed. In a first sub-period of the period, the distribution transistor of the first pixel may be activated and the distribution transistor of the second pixel may be not activated, and in a second sub-period of the period, the distribution transistor of the first pixel may be not activated and the distribution transistor of the second pixel may be activated.

The display apparatus may further include a first data line connected to the first pixel, a second data line connected to the second pixel, an output line connected to the first data line and the second data line and a data driving circuit connected to the output line and configured to supply the data signal through the output line.

According to an embodiment of the disclosure, there is provided an electronic apparatus comprising the display apparatus

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 1B are schematic views of a display apparatus according to an embodiment;

FIG. 2 is a schematic view of a display apparatus according to an embodiment;

FIG. 3 is a schematic view of a gate driving circuit and a pixel according to an embodiment;

FIGS. 4 and 5 are schematic views of an equivalent circuit of a pixel according to an embodiment;

FIGS. 6A and 6B are a schematic view of a switching device (which is a portion of a pixel) and a control signal, respectively, according to an embodiment;

FIGS. 7A and 7B are a schematic view of a switching device (which is a portion of a pixel) and a control signal, respectively, according to an embodiment;

FIG. 8 is a schematic circuit diagram of an odd column pixel and an even column pixel according to an embodiment;

FIG. 9 is a timing diagram for describing an operation of the odd column pixel and the even column pixel of FIG. 8;

FIG. 10 is a schematic circuit diagram of an odd column pixel and an even column pixel according to an embodiment;

FIG. 11 is a timing diagram for describing an operation of the odd column pixel and the even column pixel of FIG. 10;

FIG. 12 is a schematic circuit diagram of an odd column pixel and an even column pixel according to an embodiment; and

FIG. 13 is a timing diagram for describing an operation of the odd column pixel and the even column pixel of FIG. 12.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.” Throughout the disclosure, the expression “at least one of a, b or c” indicates only a, only b, only c, both a and b, both a and c, both b and c, all of a, b, and c, or variations thereof.

While the disclosure is capable of various modifications and alternative forms, embodiments thereof are shown by way of example in the drawings and will herein be described in detail. Effects and characteristics of the disclosure and methods of achieving the same will become apparent by referring to the embodiments described in detail below along with the drawings. However, the disclosure is not limited to the embodiments disclosed hereinafter and may be realized in various forms.

In the embodiments described hereinafter, the terms “first,” “second,” etc. are used to distinguish an element from another and are not used as a restrictive sense.

As used herein, the singular expressions “a,” “an,” and “the” are intended to include the plural forms as well, unless the context clearly indicates otherwise.

It will be further understood that the terms “comprises” and “including” (including variations such as “comprising”) used herein specify the presence of stated features or elements, but do not preclude the presence or addition of one or more other features or elements.

It will be understood that when a layer, region, or element is referred to as being formed “on” another layer, area, or element, it can be directly or indirectly formed on the other layer, region, or element. That is, for example, intervening layers, regions, or elements may be present.

Sizes of elements in the drawings may be exaggerated for convenience of explanation. For example, sizes and thicknesses of the elements in the drawings are randomly indicated for convenience of explanation, and thus, the disclosure is not necessarily limited to the illustrations of the drawings.

In the embodiments described hereinafter, when X and Y are referred to as being connected to each other, it may indicate cases where X and Y are physically connected to each other, X and Y are functionally connected to each other, and X and Y are electrically connected to each other. Also, when X and Y are referred to as being connected to each other, it may indicate a case where X and Y are directly connected to each other or a case where X and Y are indirectly connected to each other with another component arranged therebetween. Here, X and Y may be elements (e.g., devices, elements, circuits, lines, electrodes, terminals, films, layers, regions, etc.).

For example, when X and Y are referred to as being electrically connected to each other, it may indicate a case where X and Y are directly and electrically connected to each other or a case where X and Y are indirectly connected to each other with another component arranged therebetween. The case where X and Y are indirectly connected to each other may include a case where at least one device (e.g., a switch, a transistor, a capacitance device, an inductor, a resistance device, a diode, etc.) for allowing electrical connection between X and Y is connected between X and Y. Thus, X and Y are not limited to a predetermined connection relationship, for example, a connection relationship indicated in the drawings or the detailed description. Rather, X and Y may include other connection relationships in addition to the connection relationship indicated in the drawings or the detailed description.

In the embodiments described hereinafter, the terms “on” and “off” used in relation to a device state refer to an activated state of the device and a non-activated state of the device, respectively. The terms “on” and “off” used in relation to a signal received by a device may refer to signals configured to activate the device and non-activate the device, respectively. A device may be activated by a high level voltage or a low level voltage. For example, a P-channel transistor (a P-type transistor) may be activated by a low level voltage, and an N-channel transistor (an N-type transistor) may be activated by a high level voltage. Thus, it shall be understood that “on” voltages with respect to the P-type transistor and the N-type transistor may be opposite voltages (low versus high) to each other.

In the embodiments described hereinafter, an x direction, a y direction, and a z direction are not limited to directions in three axes on a rectangular coordinate system and may be interpreted in a broader sense. For example, the x direction, the y direction, and the z direction may be perpendicular to one another or may refer to different directions that are not perpendicular to one another.

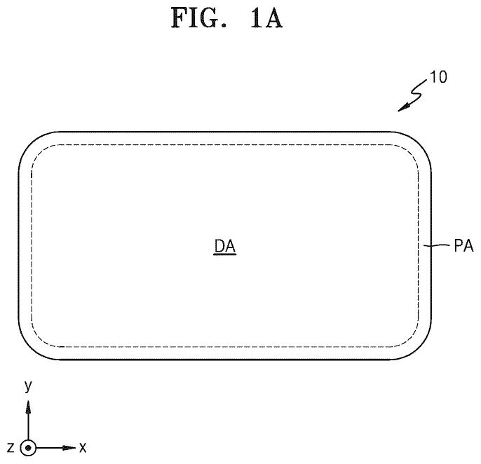

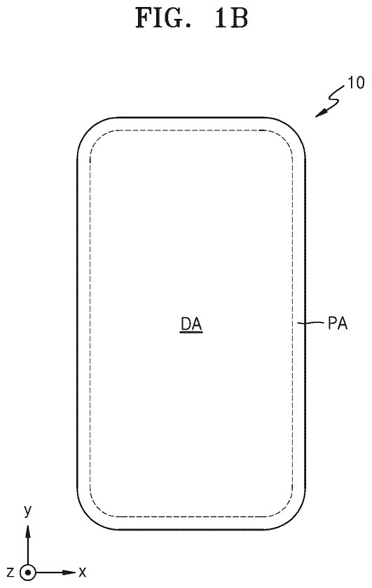

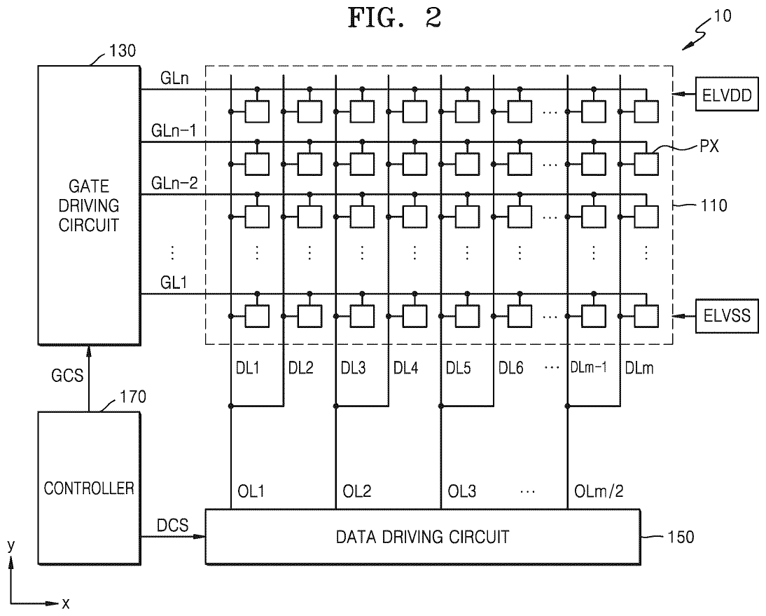

FIGS. 1A and 1B are schematic views of a display apparatus 10 according to an embodiment. FIG. 2 is a schematic view of the display apparatus 10 according to an embodiment.

Referring to FIGS. 1A and 1B, the display apparatus 10 may include a display area DA for displaying an image and a peripheral area PA outside the display area DA. The display area DA may be entirely surrounded by the peripheral area PA.

In a plan view, the display area DA may have a rectangular shape. According to another embodiment, the display area DA may have a polygonal shape, such as a triangular shape, a pentagonal shape, a hexagonal shape, etc., a circular shape, an oval shape, an amorphous shape, etc. The display area DA may have a round corner. According to an embodiment, the display apparatus 10 may have the display area DA having a shape in which the length of the display area DA in an x direction is greater than the length of the display area DA in a y direction, as illustrated in FIG. 1A. According to another embodiment, the display apparatus 10 may have the display area DA having a shape in which the length of the display area DA in the y direction is greater than the length of the display area DA in the x direction, as illustrated in FIG. 1B.

Referring to FIG. 2, the display apparatus 10 according to an embodiment may include a pixel area 110, a gate driving circuit 130, a data driving circuit 150, and a controller 170. The display apparatus 10 may include a display panel, and the display panel may include a substrate.

The pixel area 110 may correspond to the display area DA of the substrate. A plurality of gate lines GL1 to GLn, a plurality of data lines DL1 to DLm, and a plurality of pixels PX connected thereto may be arranged in the pixel area 110. The plurality of pixels PX may be arranged in various arrangement forms, for example, a stripe form, a pentile form, a diamond form, a mosaic form, etc.

According to an embodiment, when the display apparatus 10 is an organic electroluminescence light-emitting display apparatus, the pixels PX may be driven by receiving a driving voltage ELVDD and a common voltage ELVSS. The pixel PX may include an organic light-emitting diode as a display element (a light-emitting device), and the organic light-emitting diode may be connected to a pixel circuit. The pixel PX may emit, for example, red, green, blue, or white light through the organic light-emitting diode. The pixel PX may be connected to a corresponding gate line from among the plurality of gate lines GL1 to GLn and a corresponding data line from among the plurality of data lines DL1 to DLm.

The pixel circuit may include a plurality of transistors and at least one capacitor. According to an embodiment, some of the plurality of transistors included in the pixel circuit may be P-type transistors and the others may be N-type transistors. According to another embodiment, the plurality of transistors included in the pixel circuit may be P-type transistors. According to another embodiment, the plurality of transistors included in the pixel circuit may be N-type transistors. The P-type transistor may include a silicon transistor. The N-type transistor may include an oxide transistor.

The silicon transistor may include a low temperature poly-silicon (LTPS) thin-film transistor including a semiconductor layer including amorphous silicon, poly silicon, etc. The oxide transistor may include a low temperature polycrystalline oxide (LTPO) thin-film transistor including a semiconductor layer including an oxide. However, they are only examples, and the N-type transistors are not limited thereto. For example, the semiconductor layer included in the N-type transistor may include an inorganic semiconductor (e.g., amorphous silicon, poly silicon, etc.) or an organic semiconductor.

Each of the gate lines GL1 to GLn may extend in the x direction (a row direction) and may be connected to the pixels PX arranged in the same row (horizontal line). Each of the gate lines GL may be configured to transmit a gate signal to the pixels PX arranged in the same row. Each of the data lines DL1 to DLm may extend in the y direction (a column direction) and may be connected to the pixels PX arranged in the same column (vertical line). Each of the data lines DL1 to DLm may be configured to transmit a data signal, in synchronization to the gate signal, to the pixels PX in the same column.

According to an embodiment, the peripheral area PA may be a non-display area in which the pixels PX are not arranged. In the peripheral area PA of the substrate, various conductive lines configured to transmit an electrical signal to be applied to the display area DA, external circuits electrically connected to the pixel circuits, or pads to which a printed circuit board or a driver integrated circuit (IC) chip is attached, may be located. For example, the gate driving circuit 130, the data driving circuit 150, and the controller 170 may be provided in the peripheral area PA.

The gate driving circuit 130 may be connected to the plurality of gate lines GL1 to GLn, configured to generate a gate signal in response to a driving control signal GCS from the controller 170, and configured to supply the gate signal sequentially to the gate lines GL1 to GLn. Each of the gate lines GL1 to GLn may be connected to a gate of a transistor included in the pixel PX. The gate signal may be a gate control signal configured to control turning on and turning off of the transistor connected to the gate lines GL1 to GLn. The gate signal may be a signal including a gate-on voltage for turning on the transistor and a gate-off voltage for turning off the transistor. As used herein, “turning on” may be referred to as “activating.”

FIG. 2 illustrates that the pixel PX is connected to one gate line. However, it is only an example, and the pixel PX may be connected to two or more gate lines, and the gate driving circuit 130 may be configured to supply two or more gate signals having different timings for applying the gate-on voltage to the corresponding gate lines.

The data driving circuit 150 may be connected to a plurality of output lines OL1 to OLm/2, and the plurality of output lines OL1 to OLm/2 may be connected to the plurality of data lines DL1 to DLm. Each of the plurality of output lines OL1 to OLm/2 may be connected to two data lines. Because the number of output lines is less than the number of data lines, the number of output lines connected to the data driving circuit 150 may be reduced, which may lead to the reduction of manufacturing costs. The data driving circuit 150 may be configured to supply, through the output lines OL1 to OLm/2, a data signal to the data lines DL1 to DLm in response to a driving control signal DCS from the controller 170. The data signal supplied to the data lines DL1 to DLm may be supplied to the pixel PX to which the gate signal is supplied. The data driving circuit 150 may be configured to convert input image data having a gradation, which is input from the controller 170, into the data signal in the form of a voltage or a current.

The controller 170 may be configured to generate driving control signals GCS and DCS based on synchronization signals that are input from the outside and supply the driving control signals GCS and DCS to the gate driving circuit 130 and the data driving circuit 150. The driving control signal GCS that is output to the gate driving circuit 130 may include a plurality of clock signals and a gate starting signal. The driving control signal DCS that is output to the data driving circuit 150 may include a plurality of clock signals and a data starting signal.

According to an embodiment, part or whole of the gate driving circuit 130 may be directly formed in the peripheral area PA of the substrate, during a process of forming, in the display area DA of the substrate, the transistor included in the pixel circuit. The data driving circuit 150 and the controller 170 may be formed as separate IC chips or as a single IC chip and may be arranged on a flexible printed circuit board (FPCB) electrically connected to a pad arranged on a side of the substrate. According to another embodiment, the data driving circuit 150 and the controller 170 may be directly arranged on the substrate by a chip on glass (COG) or a chip on plastic (COP) method.

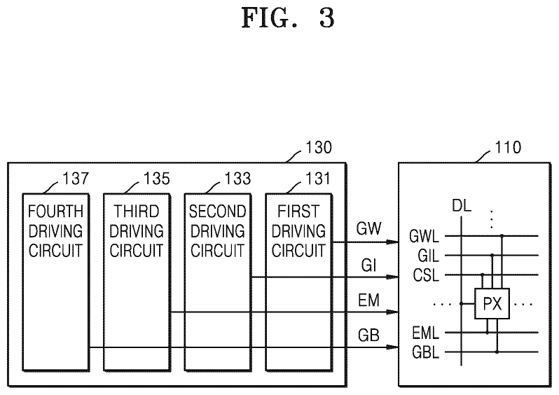

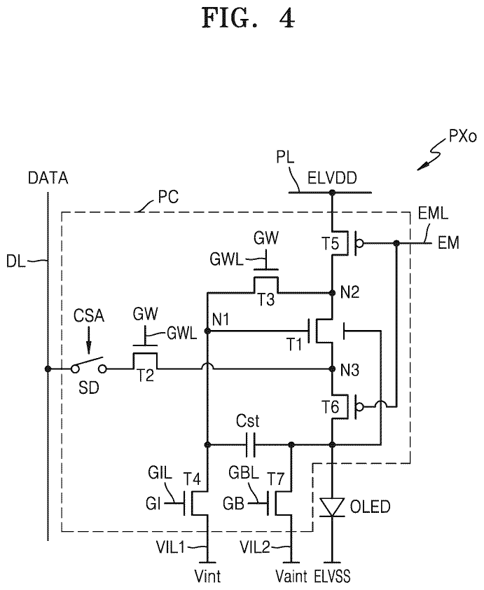

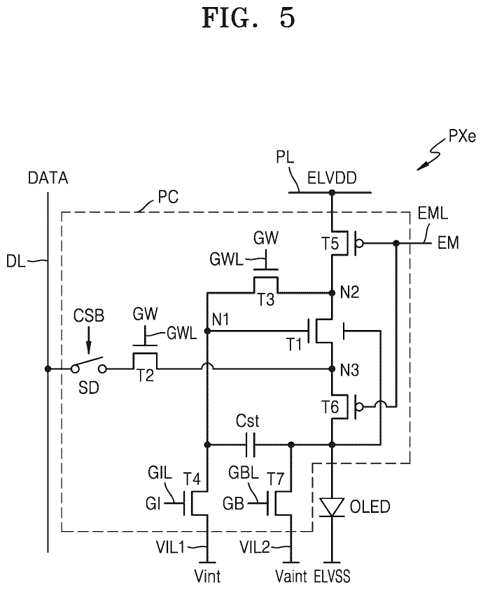

FIG. 3 is a schematic view of the gate driving circuit 130 and the pixel PX according to an embodiment. FIGS. 4 and 5 are schematic views of equivalent circuits of pixels according to an embodiment.

According to an embodiment, FIG. 4 may show a pixel arranged in an odd column and FIG. 5 may show a pixel arranged in an even column. According to another embodiment, FIG. 4 may show the pixel arranged in the even column and FIG. 5 may show the pixel arranged in the odd column. Hereinafter, it is described that FIG. 4 shows an example of a pixel PXo arranged in an odd column and FIG. 5 shows an example of a pixel PXe arranged in an even column, and the pixel PXo arranged in the odd column and the pixel PXe arranged in the even column are commonly referred to as the pixel PX.

Referring to FIG. 3, the pixel PX may be connected to a first gate line GWL, a second gate line GIL, a third gate line EML, a fourth gate line GBL, a control line CSL, and a data line DL.

The gate driving circuit 130 may include a first driving circuit 131, a second driving circuit 133, a third driving circuit 135, and a fourth driving circuit 137.

The first driving circuit 131 may be connected to a plurality of first gate lines GWL and may be configured to supply a first gate signal GW sequentially to the first gate lines GWL. The second driving circuit 133 may be connected to a plurality of second gate lines GIL and may be configured to supply a second gate signal GI sequentially to the second gate lines GIL. The third driving circuit 135 may be connected to a plurality of third gate lines EML and may be configured to supply a third gate signal EM sequentially to the third gate lines EML. The fourth driving circuit 137 may be connected to a plurality of fourth gate lines GBL and may be configured to supply a fourth gate signal GB sequentially to the fourth gate lines GBL.

According to an embodiment, the control line CSL may be one of the first gate line GWL, the second gate line GIL, the third gate line EML, and the fourth gate line GBL. A control signal supplied to the control line CSL may be a gate signal output by one of the first driving circuit 131, the second driving circuit 133, the third driving circuit 135, and the fourth driving circuit 137. One of the first driving circuit 131, the second driving circuit 133, the third driving circuit 135, and the fourth driving circuit 137 may be connected to a plurality of control lines CSL and may be configured to supply the gate signal to the control lines CSL as the control signal.

Referring to FIGS. 3, 4, and 5, the control signal may include a first control signal CSA supplied to the control line CSL of the pixel PXo (hereinafter, referred to as an “odd column pixel”) arranged in the odd column and a second control signal CSB supplied to the control line CSL of the pixel PXe (hereinafter referred to as an “even column pixel”) arranged in the even column. The first control signal CSA and the second control signal CSB may be supplied to the odd column pixel PXo and the even column pixel PXe, respectively, and may not overlap each other.

According to an embodiment, the control line CSL of the odd column pixel PXo and the control line CSL of the even column pixel PXe may be separately provided. The first control signal CSA and the second control signal CSB may be the gate signals supplied from the same driving circuit with a delay of a time difference.

According to an embodiment, the control line CSL of the odd column pixel PXo and the control line CSL of the even column pixel PXe may be integrally provided with each other, and the odd column pixel PXo and the even column pixel PXe may be connected to one control line CSL. The first control signal CSA and the second control signal CSB may be one signal and may be the gate signal supplied to the control line CSL from the driving circuit.

Referring to FIGS. 4 and 5, the pixel PX according to an embodiment may include a pixel circuit PC and a light-emitting device connected to the pixel circuit PC. According to an embodiment, the light-emitting device may include an organic light-emitting diode OLED.

The pixel circuit PC may include first to seventh transistors T1 to T7, a capacitor Cst, and a switching device SD. The first transistor T1 may be a driving transistor configured to output a driving current corresponding to a data signal, and the second to seventh transistors T2 to T7 may be switching transistors configured to transmit a signal. A first terminal (a first electrode) and a second terminal (a second electrode) of each of the first to seventh transistors T1 to T7 and the switching device SD may be a source or a drain according to voltages of the first terminal and the second terminal. For example, according to the voltages of the first terminal and the second terminal, the first terminal may be a drain and the second terminal may be a source or the first terminal may be a source and the second terminal may be a drain. A node to which a gate of the first transistor T1 is connected may be defined as a first node N1, a node to which the first terminal of the first transistor T1 is connected may be defined as a second node N2, and a node to which the second terminal of the first transistor T1 is connected may be defined as a third node N3.

The first to fourth transistors T1 to T4 and the seventh transistor T7 may be N-type transistors and the fifth and sixth transistors T5 and T6 may be P-type transistors.

The first transistor T1 may be connected between a driving voltage line PL and the organic light-emitting diode OLED. The first transistor T1 may be connected to the fifth transistor T5 and the sixth transistor T6. The first transistor T1 may include the gate (or a first gate) connected to the first node N1, the first terminal connected to the second node N2, and the second terminal connected to the third node N3. The first terminal of the first transistor T1 may be connected to the driving voltage line PL through the fifth transistor T5, and the second terminal of the first transistor T1 may be connected to a pixel electrode of the organic light-emitting diode OLED through the sixth transistor T6.

The first transistor T1 may further include a back gate (or a second gate) connected to the pixel electrode of the organic light-emitting diode OLED. The gate and the back gate may be arranged on different layers from each other to face each other. For example, the gate and the back gate of the first transistor T1 may overlap a channel area with a semiconductor layer therebetween and may be arranged face each other.

The second transistor T2 may be connected between the data line DL and the third node N3. The second transistor T2 may be connected to the switching device SD and the third node N3. The second transistor T2 may include a gate connected to the first gate line GWL, the first terminal connected to the switching device SD, and the second terminal connected to the third node N3. The second transistor T2 may be turned on in response to a first gate signal GW supplied from the first gate line GWL and may be configured to electrically connect the data line DL to the third node N3 when the switching device SD is turned on and transmit a data signal DATA transmitted through the data line DL to the third node N3.

As used herein, “turned on” may be referred to as “activated” and “turned off” may be referred to as “not activated.”

The third transistor T3 may be connected to the gate of the first transistor T1 and the first terminal of the first transistor T1. The third transistor T3 may include a gate connected to the first gate line GWL, the first terminal connected to the second node N2, and the second terminal connected to the first node N1. The third transistor T3 may be turned on in response to the first gate signal GW supplied from the first gate line GWL and may be configured to diode-connect the first transistor T1 and compensate for a threshold voltage of the first transistor T1.

The fourth transistor T4 may be connected to the gate of the first transistor T1 and a first initialization voltage line VIL1. The fourth transistor T4 may include a gate connected to the second gate line GIL, the first terminal connected to the first node N1, and the second terminal connected to the first initialization voltage line VIL1. The fourth transistor T4 may be turned on in response to a second gate signal GI supplied from the second gate line GIL and may be configured to transmit an initialization voltage Vint transmitted through the first initialization voltage line VIL1 to the first node N1.

The fifth transistor T5 may be connected to the driving voltage line PL and the first terminal of the first transistor T1. The fifth transistor T5 may include a gate connected to the third gate line EML, the first terminal connected to the driving voltage line PL, and the second terminal connected to the second node N2. The fifth transistor T5 may be turned on or turned off in response to a third gate signal EM supplied from the third gate line EML.

The sixth transistor T6 may be connected to the first transistor T1 and the organic light-emitting diode OLED. The sixth transistor T6 may be connected to the third node N3 and the organic light-emitting diode OLED. The sixth transistor T6 may include a gate connected to the third gate line EML, the first terminal connected to the third node N3, and the second terminal connected to the pixel electrode of the organic light-emitting diode OLED. The sixth transistor T6 may be turned on or turned off in response to the third gate signal EM supplied from the third gate line EML.

The seventh transistor T7 may be connected to the organic light-emitting diode OLED and a second initialization voltage line VIL2. The seventh transistor T7 may include a gate connected to the fourth gate line GBL, the first terminal connected to the second terminal of the sixth transistor T6 and the pixel electrode of the organic light-emitting diode OLED, and the second terminal connected to the second initialization voltage line VIL2. The seventh transistor T7 may be turned on in response to a fourth gate signal GB received through the fourth gate line GBL and may be configured to transmit a second initialization voltage Vaint to the pixel electrode of the organic light-emitting diode OLED to initialize the pixel electrode of the organic light-emitting diode OLED.

The capacitor Cst may be connected to the gate of the first transistor T1 and the organic light-emitting diode OLED. A first electrode of the capacitor Cst may be connected to the first node N1, and a second electrode may be connected to the pixel electrode of the organic light-emitting diode OLED. The capacitor Cst may be a storage capacitor and may be configured to store a voltage corresponding to the threshold voltage of the first transistor T1 and the data signal DATA.

The organic light-emitting diode OLED may be connected to the first transistor T1 through the sixth transistor T6. The organic light-emitting diode OLED may include the pixel electrode (an anode) connected to the second terminal of the sixth transistor T6 and the second electrode of the capacitor Cst and an opposite electrode (a cathode) facing the pixel electrode, the opposite electrode being capable of receiving a common voltage ELVSS. The opposite electrode may be a common electrode which is common to a plurality of pixels PX. A driving current output by the first transistor T1 may flow through the organic light-emitting diode OLED through the fifth transistor T5 turned on and the sixth transistor T6 turned on, and the organic light-emitting diode OLED may emit light by a brightness corresponding to a magnitude of the driving current.

The switching device SD may be connected to the data line DL and the second transistor T2. The switching device SD may include a switching transistor including a gate connected to the control line CSL. The switching device SD of the odd column pixel PXo may be turned on in response to the first control signal CSA and may be configured to transmit the data signal DATA transmitted through the data line DL to the first terminal of the second transistor T2. The switching device SD of the even column pixel PXe may be turned on in response to the second control signal CSB and may be configured to transmit the data signal DATA transmitted through the data line DL to the first terminal of the second transistor T2.

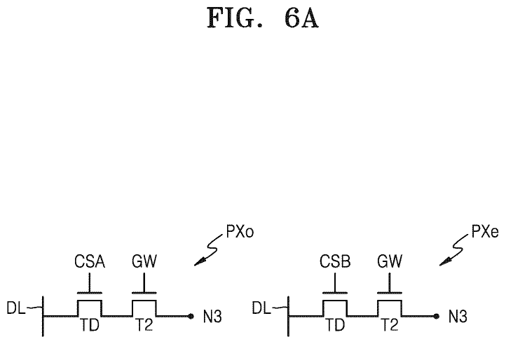

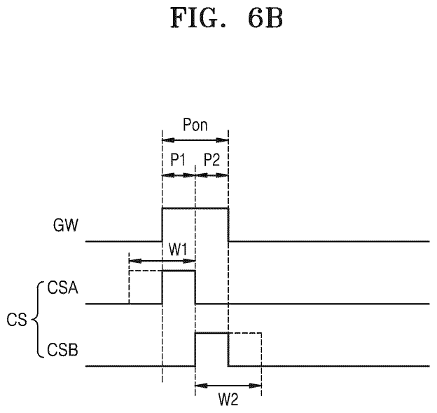

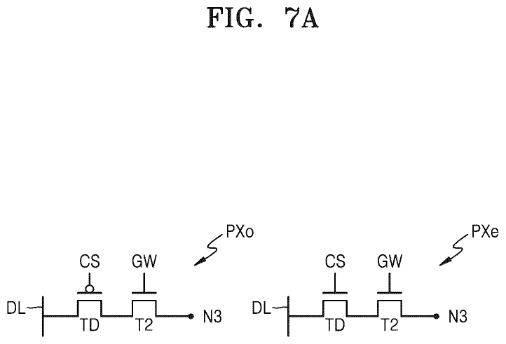

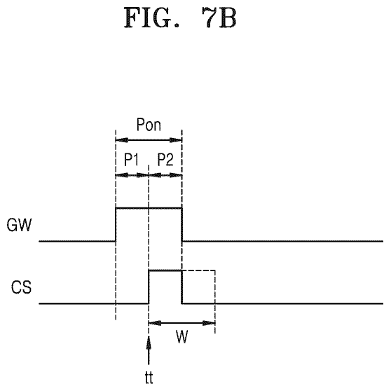

FIGS. 6A and 6B are a schematic view of a switching device (which is a portion of a pixel) and a control signal, respectively, according to an embodiment. FIGS. 7A and 7B are a schematic view of a switching device (which is a portion of a pixel) and a control signal, respectively, according to an embodiment.

The switching device SD may be connected to the data line DL and the second transistor T2 and may be realized as an N-type transistor or a P-type transistor (hereinafter, referred to as a “distribution transistor TD”).

According to an embodiment, the distribution transistors TD of the odd column pixel PXo and the even column pixel PXe may be transistors of the same conductivity type (for example, the impurity conductivity type). For example, as illustrated in FIG. 6A, each of the distribution transistors TD of the odd column pixel PXo and the distribution transistor TD of the even column pixel PXe may be an N-type transistor. As illustrated in FIG. 6B, while the first gate signal GW is being simultaneously supplied to the odd column pixel PXo and the even column pixel PXe, the first control signal CSA and the second control signal CSB may be sequentially supplied to the odd column pixel PXo and the even column pixel PXe, respectively.

Hereinafter, for convenience of explanation, that an arbitrary signal is supplied may denote that a gate-on voltage (for example, a low level voltage supplied to a P-type transistor or a high level voltage supplied to an N-type transistor) is supplied, and that an arbitrary signal is not supplied may denote that a gate-off voltage (for example, a high level voltage supplied to the P-type transistor or a low level voltage supplied to the N-type transistor) is supplied.

During a first section P1 of a section Pon in which the second transistors T2 of the odd column pixel PXo and the even column pixel PXe are turned on in response to the first gate signal GW, the distribution transistor TD of the odd column pixel PXo may be turned on in response to the first control signal CSA and the distribution transistor TD of the even column pixel PXe may be turned off in response to the second control signal CSB. During a second section P2 following the first section P1, the distribution transistor TD of the even column pixel PXe may be turned on in response to the second control signal CSB and the distribution transistor TD of the odd column pixel PXo may be turned off in response to the first control signal CSA.

As used herein, a “section” may be referred to as a “period,” and “a first section of a section” and “a second section of the section” may be referred to as “a first sub-period of a period” and “a second sub-period of the period,” respectively.

Each of a section in which the first control signal CSA is a gate-on voltage and a section in which the second control signal CSB is a gate-on voltage may overlap at least the section Pon in which the first gate signal GW is a gate-on voltage. The section in which the first control signal CSA is the gate-on voltage and the section in which the second control signal CSB is the gate-on voltage may not overlap each other. The duration (or the width) W1 during which the gate-on voltage of the first control signal CSA is maintained may not overlap the second section P2 and may be greater than the length of the first section P1. The width W2 of the gate-on voltage of the second control signal CSB may not overlap the first section P1 and may be greater than the length of the second section P2. The width W1 of the gate-on voltage of the first control signal CSA and the width W2 of the gate-on voltage of the second control signal CSB may be the same as each other.

According to an embodiment, the distribution transistors TD of the odd column pixel PXo and the even column pixel PXe may be transistors of different conductivity types. For example, as illustrated in FIG. 7A, the distribution transistor TD of the odd column pixel PXo may be the P-type transistor and the distribution transistor TD of the even column pixel PXe may be the N-type transistor. As illustrated in FIG. 7B, while the first gate signal GW is being simultaneously supplied to the odd column pixel PXo and the even column pixel PXe, the control signal CS may be simultaneously supplied to the odd column pixel PXo and the even column pixel PXe.

During the section Pon in which the second transistors T2 of the odd column pixel PXo and the even column pixel PXe are turned on in response to the first gate signal GW, a voltage level of the control signal CS may be changed. During the first section P1, the distribution transistor TD of the odd column pixel PXo may be turned on and the distribution transistor TD of the even column pixel PXe may be turned off in response to the control signal CS of a low level. The control signal CS of the low level may correspond to a gate-on voltage of the P-type transistor and a gate-off voltage of the N-type transistor. Next, during the second section P2, the distribution transistor TD of the odd column pixel PXo may be turned off and the distribution transistor TD of the even column pixel PXe may be turned on in response to the control signal CS of a high level. The control signal CS of the high level may correspond to a gate-off voltage of the P-type transistor and a gate-on voltage of the N-type transistor.

Based on a time point tt at which the control signal CS is changed from a low level voltage to a high level voltage, each of a section in which the control signal CS is the low level voltage and a section in which the control signal CS is the high level voltage may overlap at least the section Pon in which the first gate signal GW is the gate-on voltage. The width W of the high level voltage of the control signal CS may be greater than the length of the second section P2. The length of a section in which the first gate signal GW of a high level voltage and the control signal CS of the low level voltage overlap each other and the length of a section in which the first gate signal GW of the high level voltage and the control signal CS of the high level voltage overlap each other may be the same as each other.

Hereinafter, time-divisional writing of a data signal to a pixel will be described, with an example of a pair of the odd column pixel PXo and the even column pixel PXe of a kth row (pixel line), which are adjacent to each other.

A k−1th gate signal may be a gate signal output by the gate driving circuit 130 in a k−1th order, a kth gate signal may be a gate signal output by the gate driving circuit 130 in a kth order, a k+1th gate signal may be a gate signal output by the gate driving circuit 130 in a k+1th order, and a k+2th gate signal may be a gate signal output by the gate driving circuit 130 in a k+2th order.

The k−1th gate signal (a previous gate signal) may be output by a gate line in a k−1th row, the kth gate signal (a current gate signal) may be output by a gate line in a kth row, the k+1th gate signal (a next gate signal) may be output by a gate line in a k+1th row, and the k+2th gate signal (a next gate signal) may be output by a gate line in a k+2th row. According to an embodiment, a gate line connected to the gate line in the k−1th row (a previous row) or a gate line connected to the gate line in the k+1th row (a next row) or the k+2th row (a row after a next row) may further be arranged in the kth row (a current row).

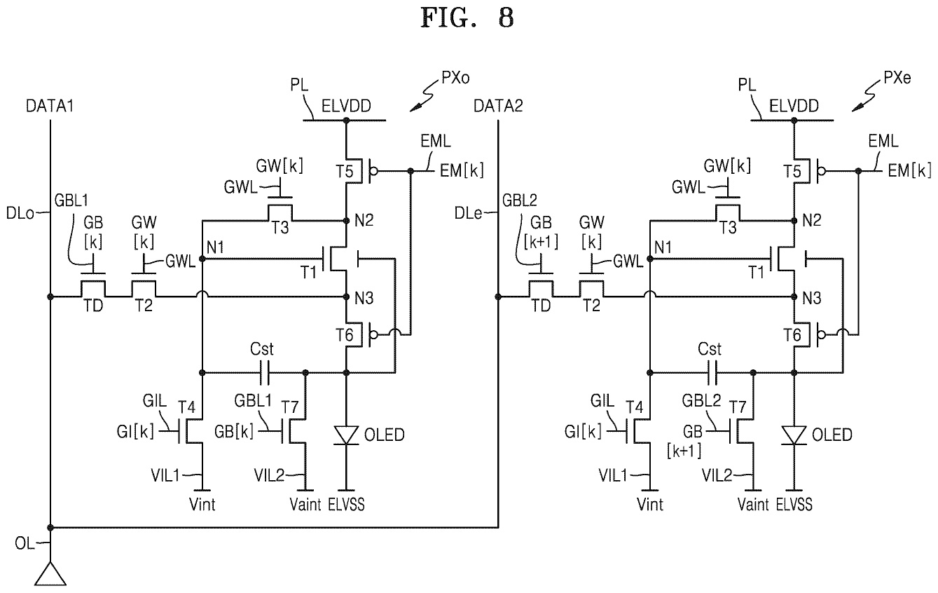

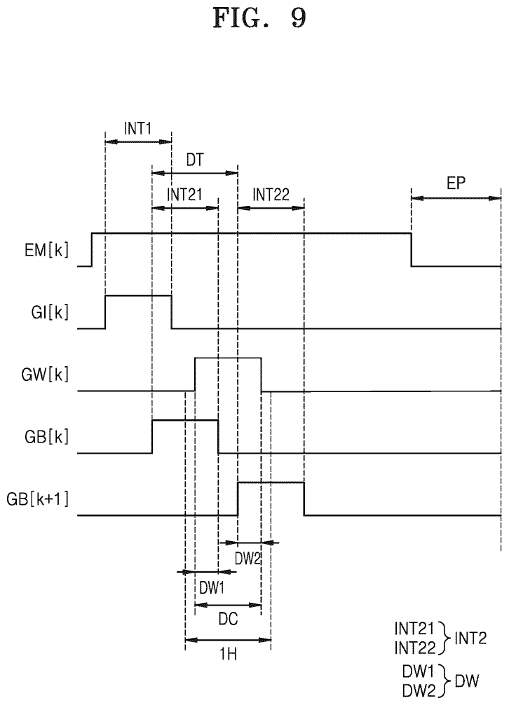

FIG. 8 is a schematic circuit diagram of an odd column pixel and an even column pixel according to an embodiment. FIG. 9 is a timing diagram for describing an operation of the odd column pixel and the even column pixel of FIG. 8.

According to an embodiment, the distribution transistor TD of the odd column pixel PXo and the distribution transistor TD of the even column pixel PXe may be N-type transistors. The control line CSL connected to the distribution transistor TD may be the fourth gate line GBL, and the control signal CS may be the fourth gate signal GB output by the fourth driving circuit 137.

Referring to FIG. 8, an output line OL may be connected to a first data line DLo connected to the odd column pixel PXo and a second data line DLe connected to the even column pixel PXe. The output line OL may be configured to sequentially supply a first data signal DATA1 to the first data line DLo and a second data signal DATA2 to the second data line DLe.

Referring to FIG. 9, a driving period of the odd column pixel PXo and the even column pixel PXe may include a first initialization section INT1, a second initialization section INT2, a data write and compensation section DC, and an emission section EP. The second initialization section INT2 may include a 2nd-1 initialization section INT21 and a 2nd-2 initialization section INT22. The data write and compensation section DC may include a first data write section DW1 and a second data write section DW2. The first data write section DW1 and the second data write section DW2 may be collectively referred to as a data write section DW

As used herein, “initialization section,” “data write and compensation section,” “emission section,” and “data write section” may be referred to as “initialization period,” “data write and compensation period,” “emission period,” and “data write period,” respectively.

The second transistors T2 and the third transistors T3 of the odd column pixel PXo and the even column pixel PXe may be configured to simultaneously receive a kth first gate signal GW[k] from the first gate line GWL. The kth first gate signal GW[k] may be a high level voltage (hereinafter, referred to as a “first level voltage”) in the data write and compensation section DC and may be a low level voltage (hereinafter, referred to as a “second level voltage”) in the remaining sections. The period (the duration or width) during which the kth first gate signal GW[k] maintains the first level voltage may be approximately a first horizontal period 1H. When the kth first gate signal GW[k] is the first level voltage, the second transistor T2 and the third transistor T3 may be turned on, and when the kth first gate signal GW[k] is the second level voltage, the second transistor T2 and the third transistor T3 may be turned off.

The fourth transistors T4 of the odd column pixel PXo and the even column pixel PXe may be configured to simultaneously receive a kth second gate signal GI[k] from the second gate line GIL. The kth second gate signal GI[k] may be the first level voltage in the first initialization section INT1 and the second level voltage in the remaining sections. When the kth second gate signal GI[k] is the first level voltage, the fourth transistor T4 may be turned on, and when the kth second gate signal GI[k] is the second level voltage, the fourth transistor T4 may be turned off.

The fifth transistors T5 and the sixth transistors T6 of the odd column pixel PXo and the even column pixel PXe may be configured to simultaneously receive a kth third gate signal EM[k] from the third gate line EML. The kth third gate signal EM[k] may be the second level voltage in the emission section EP and the first level voltage in the remaining sections. When the kth third gate signal EM[k] is the second level voltage, the fifth transistor T5 and the sixth transistor T6 may be turned on, and when the kth third gate signal EM[k] is the first level voltage, the fifth transistor T5 and the sixth transistor T6 may be turned off.

The fourth gate line GBL may include a 4th-1 gate line GBL1 and a 4th-2 gate line GBL2. According to an embodiment, the 4th-2 gate line GBL2 in a kth row may be connected to the 4th-1 gate line GBL1 in a k+1th row.

The seventh transistor T7 and the distribution transistor TD of the odd column pixel PXo may be configured to simultaneously receive a kth fourth gate signal GB[k] from the 4th-1 gate line GBL1. The kth fourth gate signal GB[k] may be the first level voltage in the 2nd-1 initialization section INT21 and the second level voltage in the remaining sections. When the kth fourth gate signal GB[k] is the first level voltage, the seventh transistor T7 and the distribution transistor TD may be turned on, and when the kth fourth gate signal GB[k] is the second level voltage, the seventh transistor T7 and the distribution transistor TD may be turned off.

The seventh transistor T7 and the distribution transistor TD of the even column pixel PXe may be configured to simultaneously receive a k+1th fourth gate signal GB[k+1] from the 4th-2 gate line GBL2. The k+1th fourth gate signal GB[k+1] may be supplied with a delay of a certain time period DT from the kth fourth gate signal GB[k]. The k+1th fourth gate signal GB[k+1] may be the first level voltage in the 2nd-2 initialization section INT22 and the second level voltage in the remaining sections. When the k+1th fourth gate signal GB[k+1] is the first level voltage, the seventh transistor T7 and the distribution transistor TD may be turned on, and when the k+1th fourth gate signal GB[k+1] is the second level voltage, the seventh transistor T7 and the distribution transistor TD may be turned off.

The 2nd-1 initialization section INT21 and the first data write section DW1 may partially overlap each other, and in the overlapping section, the first level voltage of the kth first gate signal GW[k] and the first level voltage of the kth fourth gate signal GB[k] may overlap each other.

The 2nd-2 initialization section INT22 and the second data write section DW2 may partially overlap each other, and in the overlapping section, the first level voltage of the kth first gate signal GW[k] and the first level voltage of the k+1th fourth gate signal GB[k+1] may overlap each other.

The first initialization section INT1 may be a section in which a gate voltage of the first transistor T1 is initialized. In the first initialization section INT1, the fourth transistor T4 of each of the odd column pixel PXo and the even column pixel PXe may be turned on in response to the kth second gate signal GI[k] of the first level voltage. The gate voltage of the first transistor T1 may be initialized to the first initialization voltage Vint by the fourth transistor T4 turned on.

The second initialization section INT2 may be a section in which a voltage of the pixel electrode of the organic light-emitting diode OLED is initialized. The 2nd-1 initialization section INT21 may be a section in which the voltage of the pixel electrode of the organic light-emitting diode OLED of the odd column pixel PXo is initialized. The 2nd-2 initialization section INT22 may be a section in which the voltage of the pixel electrode of the organic light-emitting diode OLED of the even column pixel PXe is initialized.

In the 2nd-1 initialization section INT21, the seventh transistor T7 may be turned on in response to the kth fourth gate signal GB[k] of the first level voltage. The voltage of the pixel electrode of the organic light-emitting diode OLED may be initialized to the second initialization voltage Vaint by the seventh transistor T7 turned on.

In the 2nd-2 initialization section INT22, the seventh transistor T7 may be turned on in response to the k+1th fourth gate signal GB[k+1] of the first level voltage. The voltage of the pixel electrode of the organic light-emitting diode OLED may be initialized to the second initialization voltage Vaint by the seventh transistor T7 turned on.

The data write and compensation section DC may be a section in which a data signal is written to the pixel PX and a threshold voltage Vth of the first transistor T1 is compensated for. A data signal may be written to the odd column pixel PXo in the first data write section DW1, and a data signal may be written to the even column pixel PXe in the second data write section DW2.

In the data write and compensation section DC, the second transistor T2 and the third transistor T3 of each of the odd column pixel PXo and the even column pixel PXe may be turned on in response to the kth first gate signal GW[k] of the first level voltage. The first transistor T1 may be diode-connected by the third transistor T3 turned on.

In the first data write section DW1, the distribution transistor TD of the odd column pixel PXo may be turned on in response to the kth fourth gate signal GB[k] of the first level voltage. The first data signal DATA1 supplied from the first data line DLo may be transmitted to the third node N3 through the distribution transistor TD and the second transistor T2 that are turned on. A voltage corresponding to the first data signal DATA1 and the threshold voltage Vth of the first transistor T1 may be stored in the capacitor Cst by an operation of the first transistor T1 diode-connected. In the first data write section DW1, the distribution transistor TD of the even column pixel PXe may be turned off in response to the k+1th fourth gate signal GB[k+1] of the second level voltage.

In the second data write section DW2, the distribution transistor TD of the even column pixel PXe may be turned on in response to the k+1th fourth gate signal GB[k+1] of the first level voltage. The second data signal DATA2 supplied from the second data line DLe may be transmitted to the third node N3 through the distribution transistor TD and the second transistor T2 that are turned on. A voltage corresponding to the second data signal DATA2 and the threshold voltage Vth of the first transistor T1 may be stored in the capacitor Cst by an operation of the first transistor T1 diode-connected. In the second data write section DW2, the distribution transistor TD of the odd column pixel PXo may be turned off in response to the kth fourth gate signal GB[k] of the second level voltage.

The emission section EP may be a section in which the organic light-emitting diode OLED emits light. In the emission section EP, the fifth transistor T5 and the sixth transistor T6 of each of the odd column pixel PXo and the even column pixel PXe may be turned on in response to the kth third gate signal EM[k] of the second level voltage. A current path from the driving voltage line PL to the organic light-emitting diode OLED may be formed through the fifth transistor T5 and the sixth transistor T6 that are turned on. The organic light-emitting diode OLED may emit light by the brightness corresponding to a driving current output by the first transistor T1.

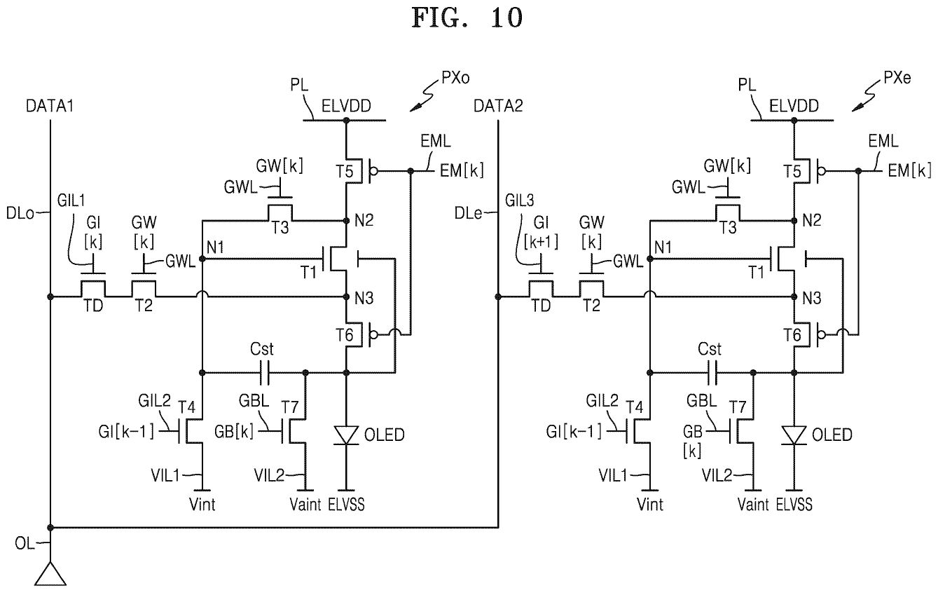

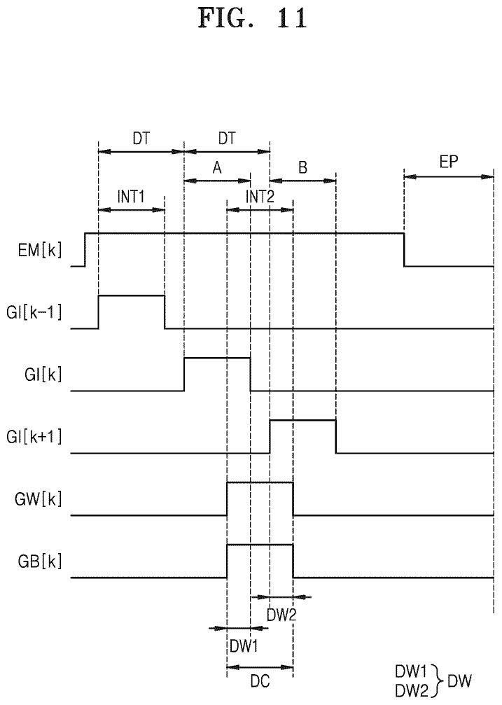

FIG. 10 is a schematic circuit diagram of an odd column pixel and an even column pixel according to an embodiment. FIG. 11 is a timing diagram for describing an operation of the odd column pixel and the even column pixel of FIG. 10.

According to an embodiment, the distribution transistor TD of the odd column pixel PXo and the distribution transistor TD of the even column pixel PXe may be N-type transistors. The control line CSL connected to the distribution transistor TD may be the second gate line GIL, and the control signal CS may be the second gate signal GI output by the second driving circuit 133.

Referring to FIG. 10, an output line OL may be connected to a first data line DLo connected to the odd column pixel PXo and a second data line DLe connected to the even column pixel PXe. The output line OL may be configured to supply a first data signal DATA1 to the first data line DLo and a second data signal DATA2 to the second data line DLe.

Referring to FIG. 11, a driving period of the odd column pixel PXo and the even column pixel PXe may include a first initialization section INT1, a second initialization section INT2, a data write and compensation section DC, and an emission section EP. The data write and compensation section DC may include a first data write section DW1 and a second data write section DW2.

The second transistors T2 and the third transistors T3 of the odd column pixel PXo and the even column pixel PXe may be configured to simultaneously receive a kth first gate signal GW[k] from the first gate line GWL. The kth first gate signal GW[k] may be the first level voltage in the data write and compensation section DC and the second level voltage in the remaining sections. The period during which the kth first gate signal GW[k] maintains the first level voltage may be approximately a first horizontal period 1H. When the kth first gate signal GW[k] is the first level voltage, the second transistor T2 and the third transistor T3 may be turned on, and when the kth first gate signal GW[k] is the second level voltage, the second transistor T2 and the third transistor T3 may be turned off.

The second gate line GIL may include a 2nd-1 gate line GIL1, a 2nd-2 gate line GIL2, and a 2nd-3 gate line GIL3. According to an embodiment, the 2nd-2 gate line GIL2 in a kth row may be connected to the 2nd-1 gate line GIL1 in a k−1th row. The 2nd-3 gate line GIL3 in the kth row may be connected to the 2nd-1 gate line GIL1 in a k+1th row.

The fourth transistors T4 of the odd column pixel PXo and the even column pixel PXe may be configured to simultaneously receive a k−1th second gate signal GI[k−1] from the 2nd-2 gate line GIL2. The k−1th second gate signal GI[k−1] may be the first level voltage in the first initialization section INT1 and the second level voltage in the remaining sections. When the k−1th second gate signal GI[k−1] is the first level voltage, the fourth transistor T4 may be turned on, and when the k−1th second gate signal GI[k−1] is the second level voltage, the fourth transistor T4 may be turned off.

The distribution transistor TD of the odd column pixel PXo may be configured to receive a kth second gate signal GI[k] from the 2nd-1 gate line GIL1. The kth second gate signal GI[k] may be supplied with a delay of a certain time period DT from the k−1th second gate signal GI[k−1]. The kth second gate signal GI[k] may be the first level voltage in a section A including the first data write section DW1 and the second level voltage in the remaining sections. When the kth second gate signal GI[k] is the first level voltage, the distribution transistor TD may be turned on, and when the kth second gate signal GI[k] is the second level voltage, the distribution transistor TD may be turned off.

The distribution transistor TD of the even column pixel PXe may be configured to receive a k+1th second gate signal GI[k+1] from the 2nd-3 gate line GIL3. The k+1th second gate signal GI[k+1] may be supplied with a delay of a certain time period DT from the kth second gate signal GI[k]. The k+1th second gate signal GI[k+1] may be the first level voltage in a section B including the second data write section DW2 and the second level voltage in the remaining sections. When the k+1th second gate signal GI[k+1] is the first level voltage, the distribution transistor TD may be turned on, and when the k+1th second gate signal GI[k+1] is the second level voltage, the distribution transistor TD may be turned off.

The fifth transistors T5 and the sixth transistors T6 of the odd column pixel PXo and the even column pixel PXe may be configured to simultaneously receive a kth third gate signal EM[k] from the third gate line EML. The kth third gate signal EM[k] may be the second level voltage in the emission section EP and the first level voltage in the remaining sections. When the kth third gate signal EM[k] is the second level voltage, the fifth transistor T5 and the sixth transistor T6 may be turned on, and when the kth third gate signal EM[k] is the first level voltage, the fifth transistor T5 and the sixth transistor T6 may be turned off.

The seventh transistors T7 of the odd column pixel PXo and the even column pixel PXe may be configured to simultaneously receive a kth fourth gate signal GB[k] from the fourth gate line GBL. The kth fourth gate signal GB[k] may be the first level voltage in the second initialization section INT2 and the second level voltage in the remaining sections. When the kth fourth gate signal GB[k] is the first level voltage, the seventh transistor T7 may be turned on, and when the kth fourth gate signal GB[k] is the second level voltage, the seventh transistor T7 may be turned off.

The data write and compensation section DC may overlap the second initialization section INT2, and in the overlapping section, the first level voltage of the kth first gate signal GW[k] and the first level voltage of the kth fourth gate signal GB[k] may overlap each other. The first level voltage of the kth first gate signal GW[k] and the first level voltage of the kth second gate signal GI[k] may overlap each other in the first data write section DW1. The first level voltage of the kth first gate signal GW[k] and the first level voltage of the k+1th second gate signal GI[k+1] may overlap each other in the second data write section DW2.

The fourth transistor T4 of each of the odd column pixel PXo and the even column pixel PXe may be turned on in response to the k−1th second gate signal GI[k−1] of the first level voltage in the first initialization section INT1. A gate voltage of the first transistor T1 may be initialized to the first initialization voltage Vint through the fourth transistor T4 turned on.

The seventh transistor T7 of each of the odd column pixel PXo and the even column pixel PXe may be turned on in response to the kth fourth gate signal GB[k] of the first level voltage in the second initialization section INT2. A voltage of the pixel electrode of the organic light-emitting diode OLED may be initialized to the second initialization voltage Vaint through the seventh transistor T7 turned on.

The second transistor T2 and the third transistor T3 of each of the odd column pixel PXo and the even column pixel PXe may be turned on in response to the kth first gate signal GW[k] of the first level voltage in the data write and compensation section DC. The first transistor T1 may be diode-connected through the third transistor T3 turned on.

The distribution transistor TD of the odd column pixel PXo may be turned on in response to the kth second gate signal GI[k] of the first level voltage in the first data write section DW1. The first data signal DATA1 supplied from the first data line DLo may be transmitted to the third node N3 through the distribution transistor TD and the second transistor T2 that are turned on. A voltage corresponding to the first data signal DATA1 and a threshold voltage Vth of the first transistor T1 may be stored in the capacitor Cst by an operation of the first transistor T1 diode-connected. The distribution transistor TD of the even column pixel PXe may be turned off in response to the k+1th second gate signal GI[k+1] of the second level voltage in the first data write section DW1.

The distribution transistor TD of the even column pixel PXe may be turned on in response to the k+1th second gate signal GI[k+1] of the first level voltage in the second data write section DW2. The second data signal DATA2 supplied from the second data line DLe may be transmitted to the third node N3 through the distribution transistor TD and the second transistor T2 that are turned on. A voltage corresponding to the second data signal DATA2 and the threshold voltage Vth of the first transistor T1 may be stored in the capacitor Cst by an operation of the first transistor T1 diode-connected. The distribution transistor TD of the odd column pixel PXo may be turned off in response to the kth second gate signal GI[k] of the second level voltage in the second data write section DW2.

The fifth transistor T5 and the sixth transistor T6 of each of the odd column pixel PXo and the even column pixel PXe may be turned on in response to the kth third gate signal EM[k] of the second level voltage in the emission section EP. A current path from the driving voltage line PL to the organic light-emitting diode OLED may be formed by the fifth transistor T5 and the sixth transistor T6 that are turned on. The organic light-emitting diode OLED may emit light by the brightness corresponding to a driving current output by the first transistor T1.

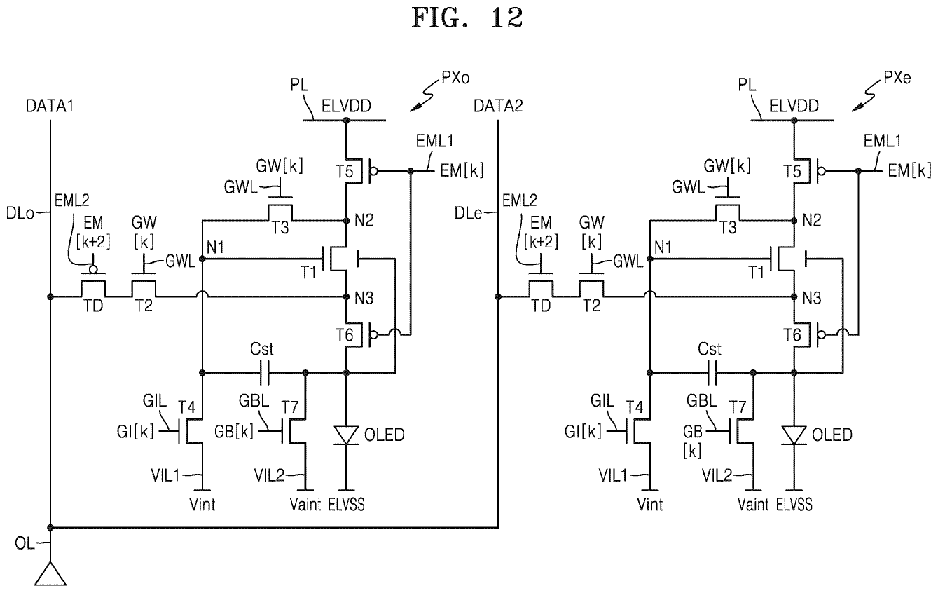

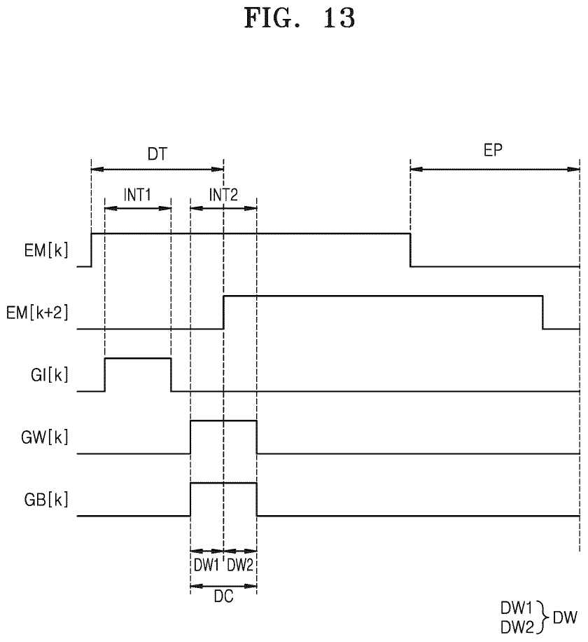

FIG. 12 is a schematic circuit diagram of an odd column pixel and an even column pixel according to an embodiment. FIG. 13 is a timing diagram for describing an operation of the odd column pixel and the even column pixel of FIG. 12.

According to an embodiment, the distribution transistor TD of the odd column pixel PXo may be a P-type transistor and the distribution transistor of the even column pixel PXe may be an N-type transistor. The control line CSL connected to the distribution transistor TD may be the third gate line EML, and the control signal CS may be the third gate signal EM output by the third driving circuit 135.

Referring to FIG. 12, an output line OL may be connected to a first data line DLo connected to the odd column pixel PXo and a second data line DLe connected to the even column pixel PXe. The data driving circuit may be configured to supply a first data signal DATA1 to the first data line DLo and a second data signal DATA2 to the second data line DLe through the output line OL.

Referring to FIG. 13, a driving period of the odd column pixel PXo and the even column pixel PXe may include a first initialization section INT1, a second initialization section INT2, a data write and compensation section DC, and an emission section EP. The data write and compensation section DC may include a first data write section DW1 and a second data write section DW2.

The second transistors T2 and the third transistors T3 of the odd column pixel PXo and the even column pixel PXe may be configured to simultaneously receive a kth first gate signal GW[k] from the first gate line GWL. The kth first gate signal GW[k] may be the first level voltage in the data write and compensation section DC and the second level voltage in the remaining sections. The period during which the kth first gate signal GW[k] maintains the first level voltage may be approximately a first horizontal period 1H. When the kth first gate signal GW[k] is the first level voltage, the second transistor T2 and the third transistor T3 may be turned on, and when the kth first gate signal GW[k] is the second level voltage, the second transistor T2 and the third transistor T3 may be turned off.

The fourth transistors T4 of the odd column pixel PXo and the even column pixel PXe may be configured to simultaneously receive a kth second gate signal GI[k] from the second gate line GIL. The kth second gate signal GI[k] may be the first level voltage in the first initialization section INT1 and the second level voltage in the remaining sections. When the kth second gate signal GI[k] is the first level voltage, the fourth transistor T4 may be turned on, and when the kth second gate signal GI[k] is the second level voltage, the fourth transistor T4 may be turned off.

The third gate line EML may include a 3rd-1 gate line EML1 and a 3rd-2 gate line EML2. According to an embodiment, the 3rd-2 gate line EML2 in a kth row may be connected to the 3rd-1 gate line EML1 in a k+2th row.

The fifth transistors T5 and the sixth transistors T6 of the odd column pixel PXo and the even column pixel PXe may be configured to simultaneously receive a kth third gate signal EM[k] from the 3rd-1 gate line EML1. The kth third gate signal EM[k] may be the second level voltage in the emission section EP and the first level voltage in the remaining sections. When the kth third gate signal EM[k] is the second level voltage, the fifth transistor T5 and the sixth transistor T6 may be turned on, and when the kth third gate signal EM[k] is the first level voltage, the fifth transistor T5 and the sixth transistor T6 may be turned off.

The distribution transistors TD of the odd column pixel PXo and the even column pixel PXe may be configured to simultaneously receive a k+2th third gate signal EM[k+2] from the 3rd-2 gate line EML2. The k+2th third gate signal EM[k+2] may be supplied with a delay of a certain time period DT from the kth third gate signal EM[k]. The k+2th third gate signal EM[k+2] may be the first level voltage from the second data write section DW2 to some portions of the emission section EP and the second level voltage in the remaining sections.

When the k+2th third gate signal EM[k+2] is the second level voltage, the distribution transistor TD of the odd column pixel PXo may be turned on and the distribution transistor TD of the even column pixel PXe may be turned off. When the k+2th third gate signal EM[k+2] is the first level voltage, the distribution transistor TD of the odd column pixel PXo may be turned off and the distribution transistor TD of the even column pixel PXe may be turned on.

The seventh transistors T7 of the odd column pixel PXo and the even column pixel PXe may be configured to simultaneously receive a kth fourth gate signal GB[k] from the fourth gate line GBL. The kth fourth gate signal GB[k] may be the first level voltage in the second initialization section INT2 and the second level voltage in the remaining sections. When the kth fourth gate signal GB[k] is the first level voltage, the seventh transistor T7 may be turned on, and when the kth fourth gate signal GB[k] is the second level voltage, the seventh transistor T7 may be turned off.

The data write and compensation section DC may overlap the second initialization section INT2, and the first level voltage of the kth first gate signal GW[k] and the first level voltage of the kth fourth gate signal GB[k] may overlap each other in the overlapping section.

In the data write and compensation section DC, the k+2th third gate signal EM[k+2] may be changed from the second level voltage to the first level voltage. The first level voltage of the kth first gate signal GW[k] and the second level voltage of the k+2th third gate signal EM[k+2] may overlap each other in the first data write section DW1. The first level voltage of the kth first gate signal GW[k] and the first level voltage of the k+2th third gate signal EM[k+2] may overlap each other in the second data write section DW2. The length of a section in which the first level voltage of the kth first gate signal GW[k] and the second level voltage of the k+2th third gate signal EM[k+2] overlap each other may be the same as the length of a section in which the first level voltage of the kth first gate signal GW[k] and the first level voltage of the k+2th third gate signal EM[k+2] overlap each other.

The fourth transistor T4 of each of the odd column pixel PXo and the even column pixel PXe may be turned on in response to the kth second gate signal GI[k] of the first level voltage in the first initialization section INT1. A gate voltage of the first transistor T1 may be initialized to the first initialization voltage Vint through the fourth transistor T4 turned on.

The seventh transistor T7 of each of the odd column pixel PXo and the even column pixel PXe may be turned on in response to the kth fourth gate signal GB[k] of the first level voltage in the second initialization section INT2. A voltage of the pixel electrode of the organic light-emitting diode OLED may be initialized to the second initialization voltage Vaint through the seventh transistor T7 turned on.

The second transistor T2 and the third transistor T3 of each of the odd column pixel PXo and the even column pixel PXe may be turned on in response to the kth first gate signal GW[k] of the first level voltage in the data write and compensation section DC. The first transistor T1 may be diode-connected through the third transistor T3 turned on.

The distribution transistor TD of the odd column pixel PXo may be turned on and the distribution transistor TD of the even column pixel PXe may be turned off in response to the k+2th third gate signal EM[k+2] of the second level voltage in the first data write section DW1. The first data signal DATA1 supplied from the first data line DLo may be transmitted to the third node N3 through the turned on distribution transistor TD and second transistor T2 of the odd column pixel PXo. A voltage corresponding to the first data signal DATA1 and a threshold voltage Vth of the first transistor T1 may be stored in the capacitor Cst by an operation of the first transistor T1 diode-connected.

The distribution transistor TD of the even column pixel PXe may be turned on and the distribution transistor TD of the odd column pixel PXo may be turned off in response to the k+2th third gate signal EM[k+2] of the first level voltage in the second data write section DW2. The second data signal DATA2 supplied from the second data line DLe may be transmitted to the third node N3 through the turned on distribution transistor TD and second transistor T2 of the even column pixel PXe. A voltage corresponding to the second data signal DATA2 and the threshold voltage Vth of the first transistor T1 may be stored in the capacitor Cst by an operation of the first transistor T1 diode-connected.

The fifth transistor T5 and the sixth transistor T6 of each of the odd column pixel PXo and the even column pixel PXe may be turned on in response to the kth third gate signal EM[k] of the second level voltage in the emission section EP. A current path from the driving voltage line PL to the organic light-emitting diode OLED may be formed by the fifth transistor T5 and the sixth transistor T6 that are turned on. The organic light-emitting diode OLED may emit light by the brightness corresponding to a driving current output by the first transistor T1.

According to an embodiment, the odd column pixel PXo and the even column pixel PXe may include the distribution transistors TD having the same conductivity type as each other. While the first gate signal GW is being supplied, the distribution transistors TD may be alternately turned on at different timings by using the second gate signal GI or the fourth gate signal GB. Thus, the data signal DATA of an odd column and the data signal DATA of an even column supplied from the output line OL may be sequentially supplied to the odd column pixel PXo and the even column pixel PXe.

According to an embodiment, the odd column pixel PXo and the even column pixel PXe may include the distribution transistors TD having different conductivity types from each other. While the first gate signal GW is being supplied, the distribution transistors TD may be alternately turned on at different timings by using the third gate signal EM. Thus, the data signal DATA of an odd column and the data signal DATA of an even column supplied from the output line OL may be sequentially supplied to the odd column pixel PXo and the even column pixel PXe.

The display apparatus according to embodiments may include the distribution transistor in the pixel and may thus selectively connect the data lines DL1 to DLm to the pixel circuit. Thus, two or more data signals supplied through one output line may be supplied to two or more data lines in a time division manner. Accordingly, it is not needed to provide an additional driving circuit configured to supply the data signal between the data driving circuit and the data lines in a time division manner, and thus, a peripheral area may be reduced and manufacturing costs may be decreased.

According to the display apparatus according to embodiments, for the control signals for controlling the distribution transistors of the odd column pixel and the even column pixel, the gate signal supplied to the transistors in the pixel circuit may be used, and thus, power consumption may be reduced without a need to supply an additional control signal. According to the embodiments described above, in the display apparatus, two data lines arranged in two columns are connected to one output line. However, embodiments are not limited thereto. For example, three or more data lines arranged in three or more columns may be connected to one output line, and the distribution transistors of the pixels arranged in the three or more columns may be sequentially turned on by using three or more gate signals each having a delay of a time difference whereby the gate-on voltages do not overlap each other, and thus, the data signals may be supplied to the three or more columns in a time division manner.

The display apparatus according to embodiments may be realized as an electronic device, such as a smartphone, a cellular phone, a smart watch, a navigation device, a game machine, a television (TV), a vehicle head unit, a notebook computer, a laptop computer, a tablet computer, a personal media player (PMP), a personal digital assistant (PDA), etc. Also, the electronic device may be a flexible device.

According to embodiments, the number of output lines of the data driving circuit may be reduced, and thus, manufacturing costs of the display apparatus may be reduced. However, the effects described above do not limit the scope of the disclosure.

It should be understood that embodiments described herein should be considered in a descriptive sense only and not for purposes of limitation. Descriptions of features or aspects within each embodiment should typically be considered as available for other similar features or aspects in other embodiments. While embodiments have been described with reference to the figures, it will be understood by one of ordinary skill in the art that various changes in form and details may be made therein without departing from the spirit and scope as defined by the following claims.

What is claimed is:

1. A display apparatus comprising:
a first pixel arranged in a row and an odd column; and
a second pixel arranged in the row and an even column, wherein each of the first pixel and the second pixel comprises:
a light-emitting diode;
a first transistor configured to output a current corresponding to a data signal;
a second transistor transmitting the data signal to the first transistor; and
a distribution transistor connected between the second transistor and a data line configured to supply the data signal,
wherein, while the second transistor of the first pixel and the second transistor of the second pixel are simultaneously activated, the distribution transistor of the first pixel and the distribution transistor of the second pixel are sequentially activated.

2. The display apparatus of claim 1, further comprising:
a first data line connected to the first pixel;
a second data line connected to the second pixel;
an output line connected to the first data line and the second data line; and
a driving circuit connected to the output line and configured to supply the data signal through the output line.

3. The display apparatus of claim 1, wherein each of the first pixel and the second pixel further comprises:
a third transistor connected to a gate of the first transistor and a first terminal of the first transistor;
a fourth transistor connected to the gate of the first transistor and a first initialization voltage line;
a fifth transistor connected to a driving voltage line and the first terminal of the first transistor;
a sixth transistor connected to a second terminal of the first transistor and the light-emitting diode;
a seventh transistor connected to the light-emitting diode and a second initialization voltage line; and
a capacitor connected to the gate of the first transistor and the light-emitting diode.

4. The display apparatus of claim 3, wherein the first transistor of each of the first pixel and the second pixel is connected to the light-emitting diode, and
the first transistor further comprises a back gate facing the gate of the first transistor.

5. The display apparatus of claim 3, further comprising:
a first gate line configured to supply a first gate signal to the second transistor and the third transistor of the first pixel, and to the second transistor and the third transistor of the second pixel;
a second gate line configured to supply a second gate signal to the fourth transistor of the first pixel and the fourth transistor of the second pixel;
a third gate line configured to supply a third gate signal to the fifth transistor and the sixth transistor of the first pixel, and to the fifth transistor and the sixth transistor of the second pixel; and
a fourth gate line configured to supply a fourth gate signal to the seventh transistor of the first pixel and the seventh transistor of the second pixel.

6. The display apparatus of claim 5, wherein a conductivity type of the distribution transistor of the first pixel is same as a conductivity type of the distribution transistor of the second pixel.

7. The display apparatus of claim 6, wherein the fourth gate signal supplied to the seventh transistor of the second pixel is delayed from the fourth gate signal supplied to the seventh transistor of the first pixel,
the fourth gate signal supplied to the seventh transistor of the first pixel and the fourth gate signal supplied to the distribution transistor of the first pixel have same timings as each other, and
the fourth gate signal supplied to the seventh transistor of the second pixel and the fourth gate signal supplied to the distribution transistor of the second pixel have same timings as each other.

8. The display apparatus of claim 7, wherein a period in which the first gate signal is a level voltage for activating the second transistor comprises a first sub-period and a second sub-period following the first sub-period,
a period in which the fourth gate signal is a level voltage for activating the distribution transistor of the first pixel overlaps the first sub-period,
a period in which the fourth gate signal is a level voltage for activating the distribution transistor of the second pixel overlaps the second sub-period, and
the period in which the fourth gate signal is the level voltage for activating the distribution transistor of the first pixel and the period in which the fourth gate signal is the level voltage for activating the distribution transistor of the second pixel do not overlap each other.

9. The display apparatus of claim 6, wherein the second gate signal delayed from the second gate signal supplied to the fourth transistor of the first pixel is supplied to the distribution transistor of the first pixel,
the second gate signal delayed from the second gate signal supplied to the fourth transistor of the second pixel is supplied to the distribution transistor of the second pixel,
the second gate signal supplied to the fourth transistor of the first pixel and the second gate signal supplied to the fourth transistor of the second pixel have same timings as each other, and
the second gate signal supplied to the distribution transistor of the second pixel is delayed from the second gate signal supplied to the distribution transistor of the first pixel.

10. The display apparatus of claim 9, wherein a period in which the first gate signal is a level voltage for activating the second transistor comprises a first sub-period and a second sub-period following the first sub-period,
a period in which the second gate signal is a level voltage for activating the distribution transistor of the first pixel overlaps the first sub-period,
a period in which the second gate signal is a level voltage for activating the distribution transistor of the second pixel overlaps the second sub-period, and
the period in which the second gate signal is the level voltage for activating the distribution transistor of the first pixel and the period in which the second gate signal is the level voltage for activating the distribution transistor of the second pixel do not overlap each other.

11. The display apparatus of claim 10, wherein a period in which the fourth gate signal is a level voltage for activating the seventh transistor overlaps the period in which the first gate signal is the level voltage for activating the second transistor.

12. The display apparatus of claim 5, wherein a conductivity type of the distribution transistor of the first pixel is different from a conductivity type of the distribution transistor of the second pixel.

13. The display apparatus of claim 12, wherein the third gate signal delayed from the third gate signal supplied to the fifth transistor of the first pixel is supplied to the distribution transistor of the first pixel and the distribution transistor of the second pixel.

14. The display apparatus of claim 13, wherein, in a period in which the first gate signal is a level voltage for activating the second transistor, a voltage level of the third gate signal supplied to the distribution transistor of the first pixel and the distribution transistor of the second pixel is changed.

15. The display apparatus of claim 14, wherein a period in which the fourth gate signal is a level voltage for activating the seventh transistor overlaps the period in which the first gate signal is the level voltage for activating the second transistor.

16. The display apparatus of claim 12, wherein a conductivity type of the fifth transistor is different from a conductivity type of the second transistor.

17. A display apparatus comprising:
a pixel area comprising a first pixel arranged in a row and an odd column and a second pixel arranged in the row and an even column; and
a gate driving circuit configured to output a gate signal to the first pixel and the second pixel, wherein each of the first pixel and the second pixel comprises:
a light-emitting diode;
a first transistor configured to output a current corresponding to a data signal;
a second transistor transmitting the data signal to the first transistor and configured to receive a first gate signal; and
a distribution transistor connected between the second transistor and a data line configured to supply the data signal, and configured to receive a second gate signal,
wherein a conductivity type of the distribution transistor of the first pixel is same as a conductivity type of the distribution transistor of the second pixel,
the second gate signal output by the gate driving circuit to the distribution transistor of the second pixel is delayed from the second gate signal output to the distribution transistor of the first pixel, and
during a first sub-period of a period in which the second transistors of the first pixel and the second pixel are simultaneously activated in response to the first gate signal output by the gate driving circuit, the distribution transistor of the first pixel is activated and the distribution transistor of the second pixel is not activated, and during a second sub-period of the period, the distribution transistor of the first pixel is not activated and the distribution transistor of the second pixel is activated.

18. The display apparatus of claim 17, further comprising:
a first data line connected to the first pixel;
a second data line connected to the second pixel;
an output line connected to the first data line and the second data line; and
a data driving circuit connected to the output line and configured to supply the data signal through the output line.

19. A display apparatus comprising:
a pixel area comprising a first pixel arranged in a row and an odd column and a second pixel arranged in the row and an even column; and
a gate driving circuit configured to output a gate signal to the first pixel and the second pixel, wherein each of the first pixel and the second pixel comprises:
a light-emitting diode;
a first transistor configured to output a current corresponding to a data signal;
a second transistor transmitting the data signal to the first transistor and configured to receive a first gate signal; and
a distribution transistor connected between the second transistor and a data line configured to supply the data signal, and configured to receive a second gate signal,
wherein a conductivity type of the distribution transistor of the first pixel is different from a conductivity type of the distribution transistor of the second pixel,
in a period in which the second transistors of the first pixel and the second pixel are simultaneously activated in response to the first gate signal output by the gate driving circuit, a voltage level of the second gate signal output by the gate driving circuit is changed, and
in a first sub-period of the period, the distribution transistor of the first pixel is activated and the distribution transistor of the second pixel is not activated, and in a second sub-period of the period, the distribution transistor of the first pixel is not activated and the distribution transistor of the second pixel is activated.

20. The display apparatus of claim 19, further comprising:
a first data line connected to the first pixel;
a second data line connected to the second pixel;
an output line connected to the first data line and the second data line; and
a data driving circuit connected to the output line and configured to supply the data signal through the output line.

21. An electronic apparatus comprising the display apparatus of one of claim 1.
